(19) United States
(12) Patent Application Publication
(10) Pub. No.: US 2013/0063126 A1
(43) Pub. Date: Mar. 14, 2013

(54) FAN DETECTING CIRCUIT

(71) Applicants: WEI-DONG CONG, Shenzhen City (CN); KANG WU, Shenzhen City (CN)

(72) Inventors: WEI-DONG CONG, Shenzhen City (CN); KANG WU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/570,232

(22) Filed: Aug. 8, 2012

(30) Foreign Application Priority Data
Sep. 14, 2011 (CN) 201110271249.2

(51) Int. Cl. G01R 19/00

(52) U.S. Cl. 324/76.11

(57) ABSTRACT

A fan detecting circuit used to detect whether a fan is connected to an electronic device, includes a connector, a control unit, a display unit, and first and second electronic switches. The connector includes a detecting pin connected to a power supply through a resistor. When the fan is not connected to the connector, the control unit receives a high level signal from the power supply, and controls the display unit to indicate the fan is not connected to the electronic device. When the fan is connected to the connector, the detecting pin of the connector is grounded through the fan, and the first and second electronic switches are turned on. The connector is grounded through the second electronic switch. The control unit receives a low level signal from the detecting pin of the connector, and controls the display unit to indicate the fan is connected to the electronic device.

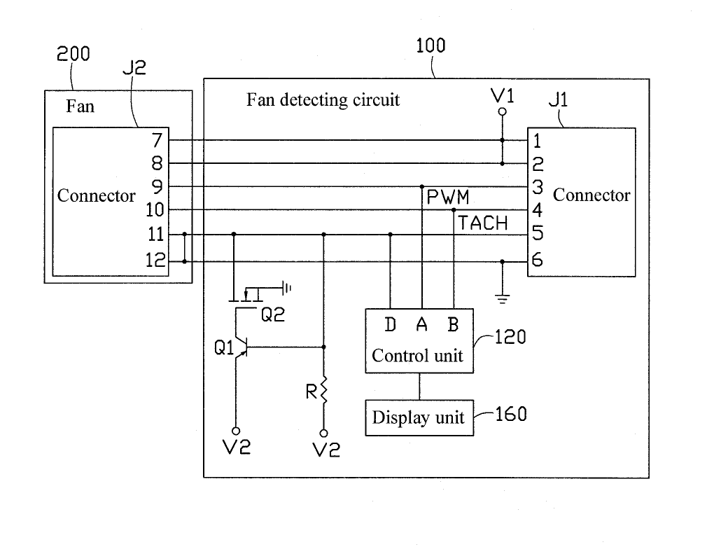

### BACKGROUND

1. Technical Field

The present disclosure relates to a fan detecting circuit.

2. Description of Related Art

Fans as cooling tools are widely used in electronic devices, such as computers and servers. The electronic devices can measure rotation speeds of the fans. However, when the electronic devices obtain rotation speeds of zero, the electronic devices may not be able to determine whether the fans are damaged or no fan is connected to the electronic devices. Therefore, there is room for improvement in the art.

### BRIEF DESCRIPTION OF THE DRAWING

Many aspects of the embodiments can be better understood with reference to the following drawing. The components in the drawing are not necessarily drawn to scale, the emphasis instead being placed upon clearly illustrating the principles of the present embodiments. Moreover, in the drawing, like reference numerals designate corresponding parts throughout the view.

The FIGURE is a circuit diagram of a fan detecting circuit in accordance with an exemplary embodiment of the present disclosure.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean at least one.

The FIGURE is an exemplary embodiment of a fan detecting circuit 100 including a connector J1, a control unit 120, a display unit 160, and two electronic switches Q1 and Q2. The fan detecting circuit 100 is used to detect whether a fan 200 is connected to an electronic device (not shown), such as a computer or a server. In one embodiment, the fan detecting circuit 100 is positioned on a circuit board of the electronic device. The fan 200 includes a connector J2 connected to the connector J1.

The connector J1 includes two power pins 1 and 2, two signal pins 3 and 4, a detecting pin 5, and a ground pin 6. The control unit 120 includes two signal pins A and B, and a detecting pin D. The power pins 1 and 2 are connected to a power supply V 1. The signal pin 3 is connected to the signal pin A. The signal pin 4 is connected to the signal pin B. The detecting pin 5 is connected to the detecting pin D. The ground pin 6 is grounded. A control terminal of the electronic switch Q1 is connected to a power supply V2 through a resistor R, and connected to the detecting pin 5. A power terminal of the electronic switch Q1 is connected to the power supply V2. A control terminal of the electronic switch Q2 is connected to an output terminal of the electronic switch Q1. An output terminal of the electronic switch Q2 is connected to the detecting pin 5. A ground terminal of the electronic switch Q2 is grounded. The display unit 160 is connected to the control unit 120. The connector J2 includes two power pins 7 and 8, two signal pins 9 and 10, and two ground pins 11 and 12. The ground pin 11 is connected to the ground pin 12. In one embodiment, the power supply V1 is a 12 volt (V) power supply, and the power supply V2 is a 3.3V power supply.

When the fan 200 is not connected to the electronic device, the connector J1 is disconnected from the connector J2. The power supply V2 supplies a high level signal to the control terminal of the electronic switch Q1. The electronic switch Q1 is turned off, and the electronic switch Q2 is turned off. The detecting pin D receives a high level signal directly from the power supply V2. The control unit 120 controls the display unit 160 to indicate the fan 200 is not connected to the electronic device.

When the fan 200 is connected to the electronic device, the connector J1 is connected to the connector J2. The power pin 1 is connected to the power pin 7. The power pin 2 is connected to the power pin 8. The signal pin 3 is connected to the signal pin 9. The signal pin 4 is connected to the signal pin 10. The detecting pin 5 is connected to the ground pin 11. The ground pin 6 is connected to the ground pin 12. The power supply V1 supplies power to the fan 200 through the power pin 1 and the power pin 7, and through the power pin 2 and the power pin 8. At the moment the fan 200 is connected to the electronic device, the detecting pin 5 is grounded through the ground pin 11, the ground pin 12, and the ground pin 6. Thereby, the control terminal of the electronic switch Q1 receives a low level signal from the detecting pin 5, and the electronic switch Q1 is turned on. The output terminal of the electronic switch Q1 outputs a high level signal to the control terminal of the electronic switch Q2, which turns on the electronic switch Q2. The detecting pin 5 is grounded through the electronic switch Q2. The detecting pin D receives a low level signal from the detecting pin 5. The control unit 120 controls the display unit 160 to indicate the fan 200 is connected to the electronic device. The control unit 120 transmits a rotation speed control signal PWM to the fan 200 through the signal pin A, the signal pin 3, and the signal pin 9. The fan 200 transmits an actual rotation speed signal TACH to the control unit 120 through the signal pin 10, the signal pin 4, and the signal pin B.

In one embodiment, the connector J1 includes two power pins 1 and 2, and the connector J1 should further includes two ground pins corresponding to the power pins 1 and 2. Then, current flowing into the fan 200 from the power pins 1 and 2 can flow into ground through the two ground pins. At the moment the fan 200 is connected to the electronic device, the connector J1 includes a single ground pin 6 to accommodate current flowing into ground. When the detecting pin 5 is grounded through the electronic switch Q2, the detecting pin 5 functions as a ground pin, and the connector J1 includes two ground pins 5 and 6 to share current flowing into ground.

In one embodiment, the two electronic switch Q1 is a pnp bipolar junction transistor. The control terminal, the power terminal, and the output terminal of the electronic switch Q1 are respectively a base, an emitter, and a collector of the pnp bipolar junction transistor. The electronic switch Q2 is an n-channel metal-oxide semiconductor field-effect transistor (NMOSFET). The control terminal, the output terminal, and the ground terminal of the electronic switch Q2 are respectively a gate, a drain, and a source of the NMOSFET. In other embodiments, the electronic switch Q1 may be an npn bipolar junction transistor, or a MOSFET, or other switch having similar functions, and the electronic switch Q2 may be a p-channel MOSFET, or a transistor, or other switch having similar functions.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A fan detecting circuit used to detect whether a fan is connected to an electronic device, the fan detecting circuit comprising:
a resistor;
a connector comprising a detecting pin connected to a first power supply through the resistor;
a control unit comprising a detecting pin connected to the detecting pin of the connector;
a display unit connected to the control unit;
a first electronic switch comprising a control terminal connected to the detecting pin of the connector, a power pin connected to the first power supply, and an output terminal; and
a second electronic switch comprising a control terminal connected to the output terminal of the first electronic switch, an output terminal connected to the detecting pin of the connector, and a ground terminal grounded;
wherein when the fan is not connected to the connector, the first power supply supplies a high level signal to the control terminal of the first electronic switch and the detecting pin of the control unit, the first electronic switch is turned off, the second electronic switch is turned off, the control unit controls the display unit to indicate the fan is not connected to the electronic device; and
wherein when the fan is connected to the connector, the detecting pin of the connector is grounded through the fan, the control terminal of the first electronic switch receive a low level signal from the detecting pin of the connector, the first electronic switch is turned on, the second electronic switch is turned on, the detecting pin of the connector is grounded through the second electronic switch, the detecting pin of the control unit receives a low level signal from the detecting pin of the connector, the control unit controls the display unit to indicate the fan is connected to the electronic device.

2. The fan detecting circuit of claim 1, wherein the first electronic switch is a pnp transistor, the control terminal, the power terminal, and the output terminal of the first electronic switch are respectively a base, an emitter, and a collector of the pnp bipolar junction transistor.

3. The fan detecting circuit of claim 1, wherein the second electronic switch is an n-channel metal-oxide semiconductor field-effect transistor (NMOSFET), the control terminal, the output terminal, and the ground terminal of the second electronic switch are respectively a gate, a drain, and a source of the NMOSFET.

4. The fan detecting circuit of claim 1, wherein the first power supply is a 3.3 volt power supply.

5. The fan detecting circuit of claim 1, wherein the control unit further comprises first and second signal pins; the connector further comprises a first power pin connected to a second power supply, a second power pin connected to the first power pin, a third signal pin connected to the first signal pin of the control unit, a fourth signal pin connected to the second signal pin of the control unit, and a ground pin grounded; when the fan is connected to the connector, the second power supply supplies power to the fan through the third and fourth power pins, the control unit transmits a rotation speed control signal to the fan through the first signal pin of the control unit and the third signal pin of the connector, the fan transmits an actual rotation speed signal to the control unit through the fourth signal pin of the connector and the second signal pin of the control unit.
